(19) United States
(12) Patent Application Publication
(10) Pub. No.: US 2021/0408509 A1
(43) Pub. Date: Dec. 30, 2021

(54) ARRAY SUBSTRATE AND REPAIRING METHOD OF DISCONNECTED POINTS OF DATA LINES AND DISPLAY DEVICE THEREOF

(71) Applicant: Wuhan China Star Optoelectronics Semiconductor Display Technology Co., Ltd., Wuhan, Hubei (CN)

(72) Inventor: Le Zhang, Wuhan (CN)

(73) Assignee: Wuhan China Star Optoelectronics Semiconductor Display Technology Co., Ltd., Wuhan, Hubei (CN)

(21) Appl. No.: 16/770,708

(22) PCT Filed: Dec. 19, 2019
(86) PCT No.: PCT/CN2019/126477

§ 371 Date: Jun. 8, 2020

(30) Foreign Application Priority Data
Sep. 2, 2019 (CN) 201910822221.X

(51) Int. Cl. H01L 51/56; H01L 27/32

(52) U.S. Cl. CPC H01L 51/56; H01L 2251/568; H01L 27/3276

(57) ABSTRACT

An array substrate, and a repairing method of disconnected points of data lines and a display device thereof are provided by this disclosure. The array substrate comprises a base substrate, and a first metal layer and a source-drain electrode layer sequentially stacked on the base substrate. A plurality of data lines are disposed at intervals in the source-drain electrode layer. A plurality of repairing lines are disposed at intervals in the first metal layer. Repairing sub-lines are disposed at intervals on each of the repairing lines. When a disconnection point appears in the data lines, the repairing sub-lines located on opposite sides of the disconnection point are connected with opposite ends of the disconnection point to easily complete repairing of the disconnection points of the data lines.

### BACKGROUND OF INVENTION

### Field of Invention

This application relates to the field of display technology, and particularly relates to an array substrate, and a repairing method of disconnected points of data lines and a display device thereof.

### Description of Prior Art

Active-matrix organic light-emitting diodes (AMOLEDs) have been developing quickly due to their unique advantages. Array substrates configured to match the AMOLEDs are mainly low temperature poly-silicon (LTPS) array substrates. During manufacturing of the LTPS array substrates, it is difficult to ensure homogeneity of a large area of polysilicon semiconductor, which is embodied as threshold voltage shifts. In order to solve a problem of low homogeneity of polysilicon in AMOLED LTPS, it is necessary to use pixel compensation circuits in sub-pixel driving circuits of AMOLED LTPS array substrates to offset an impact of the threshold voltage shifts.

A current mainstream pixel compensation circuit in the prior art is designed as 7T1C. In order to manufacture such a driving circuit, a patterned polysilicon layer, patterned first metal layer, patterned second metal layer, patterned source drain electrode layer, and insulating layers disposed between conductive layers are required. Normal operation of the compensation circuit requires scanning signals, power voltage signals, data signals, light-emitting signals, positive power supply voltage signals, and negative power supply voltage signals. The scanning signals and the light-emitting signals are usually input from opposite sides of a gate on array (GOA) structure of the array substrate, which induces high tolerance for open circuit of signal lines. That is, a single disconnection of the scanning signals and the light-emitting signals will generally not result in poor quality. As for data lines, signals are input from a single side, and each of the signal lines transmits different signals, and data lines cannot be cross-linked. Thus, the data lines are sensitive to line breakages. If a disconnection point exists, poor quality will surely be induced at an end which is far away from signal input. Furthermore, with regard to short circuit which may exist in the data lines and other conductive layers, opposite ends of the short-circuit point can be cut off and then repaired according to a method of repairing line breakages. However, with regard to short circuit or open circuit of the data lines, additional repairing lines are required to assist with the repairs.

In summary, a problem that it is difficult to repair the disconnection points exists in the data lines of the pixel compensation circuits of the array substrates in prior art. Therefore, it is necessary to provide an array substrate, and a repairing method of disconnected points of data lines and a display device thereof.

### SUMMARY OF INVENTION

An array substrate, and a repairing method of disconnected points of data lines and a display device thereof are provided by embodiments of this disclosure to solve the problem that it is difficult to repair the disconnection points, which exists in data lines of the pixel compensation circuits of the array substrates in prior art.

An array substrate is provided by embodiments of this disclosure, comprising a base substrate, and a first metal layer and a source-drain electrode layer sequentially stacked on the base substrate.

A plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines.

According to one embodiment of this disclosure, when a disconnection point appears in the data lines, the repairing sub-lines located on opposite sides of the disconnection point are connected with opposite ends of the disconnection point.

According to one embodiment of this disclosure, wherein the array substrate comprises a plurality of sub-pixel electrodes arranged in an array, each of the repairing lines corresponds to a column of the sub-pixel electrodes, and each of the repairing sub-lines is located in a gap of two adjacent sub-pixel electrodes.

According to one embodiment of this disclosure, at least one of the sub-pixel electrodes are disposed between any two adjacent repairing sub-lines on a same repairing line.

According to one embodiment of this disclosure, extending directions of the repairing sub-lines on a same repairing line are same.

According to one embodiment of this disclosure, wherein the array substrate further comprises an insulating interlayer, the insulating interlayer is disposed between the first metal layer and the source-drain electrode layer, and when a disconnection point appears in the data lines, the repairing sub-lines are connected to opposite ends of the disconnection point through a first connecting hole penetrating the insulating interlayer.

According to one embodiment of this disclosure, wherein the array substrate further comprises a second metal layer, a plurality of scanning lines are disposed at intervals in the second metal layer, and the scanning lines intersect with the data lines.

According to one embodiment of this disclosure, wherein the array substrate further comprises a polysilicon layer, the polysilicon layer is located between the second metal layer and the base substrate, a second connecting hole is provided in a region where the first metal layer intersects the polysilicon layer, and the data lines are connected to the polysilicon layer through the second connecting hole.

A repairing method of disconnection points of an array substrate is provided by embodiments of this disclosure, wherein the array substrate comprises a base substrate, and a first metal layer and a source-drain electrode layer sequentially stacked on the base substrate.

A plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines. The method comprises steps of:

finding locations of the disconnection points of the data lines; and

connecting the repairing sub-lines located on opposite sides of the disconnection points with opposite ends of the disconnection points respectively to conduct the data lines.

A display device comprising an array substrate is provided by embodiments of this disclosure, wherein the array substrate comprises a base substrate, and a first metal layer and a source-drain electrode layer sequentially stacked on the base substrate.

A plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines.

According to one embodiment of this disclosure, when a disconnection point appears in the data lines, the repairing sub-lines located on opposite sides of the disconnection point are connected with opposite ends of the disconnection point.

According to one embodiment of this disclosure, wherein the array substrate comprises a plurality of sub-pixel electrodes arranged in an array, each of the repairing lines corresponds to a column of the sub-pixel electrodes, and each of the repairing sub-lines is located in a gap of two adjacent sub-pixel electrodes.

According to one embodiment of this disclosure, at least one of the sub-pixel electrodes are disposed between any two adjacent repairing sub-lines on a same repairing line.

According to one embodiment of this disclosure, extending directions of the repairing sub-lines on a same repairing line are the same.

According to one embodiment of this disclosure, wherein the array substrate further comprises an insulating interlayer, the insulating interlayer is disposed between the first metal layer and the source-drain electrode layer, and when a disconnection point appears in the data lines, the repairing sub-lines are connected to opposite ends of the disconnection point through a first connecting hole penetrating the insulating interlayer.

According to one embodiment of this disclosure, wherein the array substrate further comprises a second metal layer, a plurality of scanning lines are disposed at intervals in the second metal layer, and the scanning lines intersect with the data lines.

According to one embodiment of this disclosure, wherein the array substrate further comprises a polysilicon layer, the polysilicon layer is located between the second metal layer and the base substrate, a second connecting hole is provided in a region where the first metal layer intersects the polysilicon layer, and the data lines are connected to the polysilicon layer through the second connecting hole.

Advantageous effects of embodiments of this disclosure are as below: a plurality of repairing lines are disposed at intervals in the first metal layer, at least two repairing sub-lines are disposed at intervals on each of the repairing lines, and each of the repairing sub-lines extends from each of the repairing lines to a position of a projection of one of the data lines on the first metal layer along a direction of a thickness of the array substrate, and is insulated from the data lines in embodiments of this disclosure. When a disconnection point appears in the data lines, the repairing sub-lines are connected with opposite ends of the disconnection point to easily complete the repairing of the disconnection points of the data lines. At the same time, the repairing lines are disposed in the first metal layer, reducing space of the array substrate occupied by the repairing lines and simplifying a film structure of the array substrate.

### BRIEF DESCRIPTION OF DRAWINGS

In order to more clearly illustrate the technical solution of embodiments or prior art, a brief description of the drawings that are necessary for the illustration of the embodiments or prior art will be given as follows. Obviously, the drawings described below show only some embodiments of this disclosure, and a person having ordinary skill in the art may also obtain other drawings based on the drawings described without making any creative effort.

FIG. 1 is a structural schematic view of an array substrate provided by a first embodiment of this disclosure.

FIG. 2 is another structural schematic view of the array substrate provided by the first embodiment of this disclosure.

FIG. 3 is a structural schematic view of an array substrate provided by a second embodiment of this disclosure.

FIG. 4 is a flow chart of a repairing method of disconnection points of data lines of an array substrate provided by a third embodiment of this disclosure.

### DETAILED DESCRIPTION OF PREFERRED EMBODIMENTS

The description of following embodiment, with reference to the accompanying drawings, is used to exemplify specific embodiments which may be carried out in this application. The directional terms mentioned in this application, such as “up”, “down”, “front”, “back”, “left”, “right”, “inside”, “outside”, and “side surface” etc., only refer to the directions in attached drawings. Therefore, the directional terms are used to illustrate and help understand this application, but not used to limit this application. In the figures, the same reference numbers are used to represent elements with similar structures.

The disclosure will be further described in combination with the attached drawings and specific embodiments as follows:

### First Embodiment

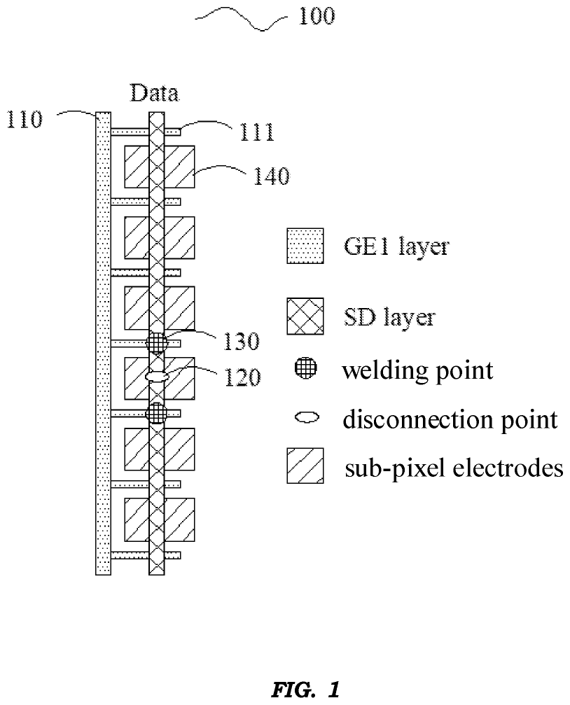

An array substrate is provided by the embodiments of this disclosure, and a detailed description will be described in combination with FIG. 1.

FIG. 1 shows is a structural schematic view of an array substrate 100 provided by embodiments of this disclosure. The array substrate 100 comprises a base substrate (not shown in the figures), and a first metal layer GE1 and a source-drain electrode layer SD sequentially stacked on the base substrate. Wherein, a plurality of data lines Data are disposed at intervals in the source-drain electrode layer SD, a plurality of repairing lines 100 are disposed at intervals in the first metal layer GE1, at least two repairing sub-lines 111 are disposed at intervals on each of the repairing lines 100, and each of the repairing sub-lines 111 extends from each of the repairing lines 110 to a position of a projection of one of the data lines Data on the first metal layer GE1 along a thickness direction of the array substrate, and is insulated from the data lines Data.

In this embodiment, the repairing lines 110 and the repairing sub-lines 111 are used to repair disconnection points of the data lines Data, so as to ensure conduction of the data lines Data. When a disconnection point 120 appears in the data lines Data, the repairing sub-lines 111 located on opposite sides of the disconnection point 120 are connected to opposite ends of the disconnection point 120, which makes the repairing lines 110 and the repairing sub-lines 111 part of the data lines Data, so that the repairing of the disconnection point 120 of the data lines Data can be completed effectively, thus ensuring a conduction of the data lines Data.

Specifically, a method of connecting the repairing sub-lines 111 with opposite ends of the disconnection point 120 includes laser welding connection. As shown in FIG. 1, dots on opposite sides of the disconnection point 120 are welding points 130. Certainly, in other embodiments, other connection repairing methods can also be applied, without specific restrictions. At the same time, a number of the repairing sub-lines 111 is not limited to 2, and can also be 3 or more.

As shown in FIG. 1, the array substrate 100 includes a plurality of sub-pixel electrodes 140 arranged in an array. Each of the repairing lines 110 corresponds to a column of the sub-pixel electrodes 140, and each of the repairing sub-lines 111 is located in a gap of two adjacent sub-pixel electrodes 140. Each of the data lines Data also corresponds to a column of the sub-pixel electrodes 140, and is used to transmit data to the whole column of pixel units.

In this embodiment, one sub-pixel electrode 140 is disposed between any two adjacent repairing sub-lines 111 on a same repairing line 110. As regions where the data lines Data intersect the repairing sub-lines 111 of the repairing lines 110 exist, when a line is conducted, a coupling capacity generated in the intersecting regions has bad effect on a transmission of data in the data lines. Therefore, it is necessary to reduce an area of the intersecting regions of the data lines Data and the repairing sub-lines 111.

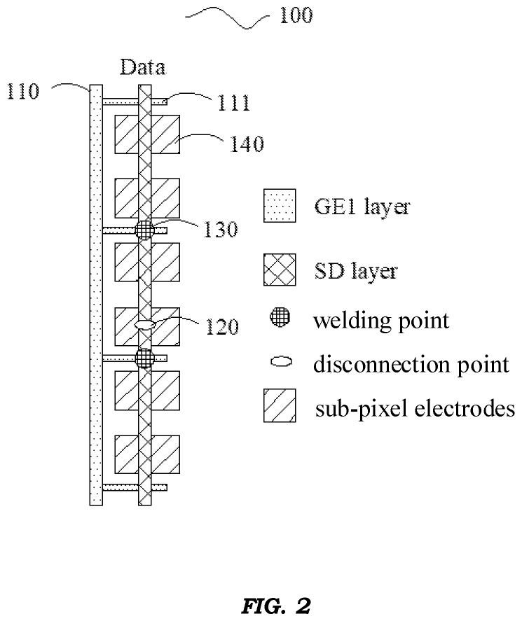

FIG. 2 shows another arrangement of repairing sub-lines. Two sub-pixel electrodes 140 are disposed between any two adjacent repairing sub-lines 111 of the repairing line 110. By means of reducing the number of the repairing sub-lines 111, the area of the intersecting regions of the data lines Data and the repairing sub-lines 111 is reduced, thus reducing the coupling capacity of the intersecting regions. Certainly, in other embodiments, more than two sub-pixel electrodes 140 can be disposed between any two adjacent repairing sub-lines 111 on the same repairing line 110.

In this embodiment, the array substrate includes a plurality of pixel compensation circuits arranged in an array, and this means the array substrate includes a plurality of data lines and a plurality of repairing lines. To ensure a repairing quality of the data lines Data, extending directions of the repairing sub-lines 111 on the same repairing line 110 are same. Each of the repairing sub-lines 111 on the same repairing line 110 extends to a position of a projection of the data line Data of the pixel compensation circuits on the first metal layer GE1 along a thickness direction of the array substrate 100, and overlaps with the position of the projection.

A plurality of repairing lines 110 are disposed at intervals in the first metal layer GE1, at least two repairing sub-lines 111 are disposed at intervals on each of the repairing lines 110, and each of the repairing sub-lines 111 extends from each of the repairing lines 110 to a position of a projection of one of the data lines Data on the first metal layer GE1 along a direction of a thickness of the array substrate, and is insulated from the data lines Data in embodiments of this disclosure. When a disconnection point appears in the data lines Data, the repairing sub-lines 111 are connected with opposite ends of the disconnection point 120 to easily complete the repairing of the disconnection points of the data lines Data. At the same time, the repairing lines 110 are disposed in the first metal layer GE1, reducing a space of the array substrate occupied by the repairing lines 110, and simplifying a film structure of the array substrate.

### Second Embodiment

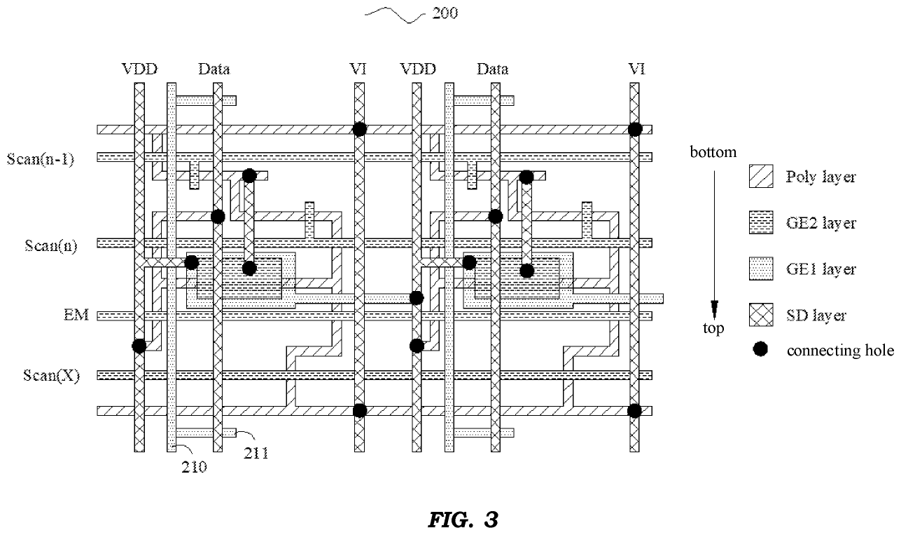

An array substrate is provided by the embodiments of this disclosure, and a detailed description will be described in combination with FIG. 3.

FIG. 3 shows a structural schematic view of an array substrate 200 provided by embodiments of this disclosure. The array substrate 200 includes a base substrate (not shown in figures) and a pixel compensation circuit of 7T1C as shown in FIG. 3 which is disposed on the base substrate. FIG. 3 only illustrates an nth stage of the pixel compensation circuit. The pixel compensation circuit includes a plurality of data lines Data and a plurality of repairing lines 210. At least two repairing sub-lines 211 are disposed at intervals on each of the repairing lines 210, and each of the repairing sub-lines 211 extends from each of the repairing lines 210 to a position of a projection of one of the data line Data on the first metal layer GE1 along a thickness direction of the array substrate, and is insulated from the data lines Data.

Specifically, the repairing lines 210 are disposed in the first metal layer GE1, the data lines Data are disposed in the source-drain electrode layer, the first metal layer GE1 is disposed on the base substrate, and the data lines Data are disposed on a side of the first metal layer GE1 away from the base substrate.

In this embodiment, the array substrate 200 further comprises an insulating interlayer (not shown in the figures), and the insulating interlayer is disposed between the first metal layer GE1 and the source-drain electrode layer SD. When a disconnection point appears in the data lines Data, the repairing sub-lines 211 are connected to opposite ends of the disconnection point through a first connecting hole penetrating the insulating interlayer, which makes the repairing lines 210 and the repairing sub-lines 211 part of the data lines Data, so that the repairing of the disconnection point 120 of the data lines can be completed effectively, thus ensuring a conduction of the data lines Data.

Specifically, a method of connecting the repairing sub-lines 211 with opposite ends of the disconnection point includes laser welding connection. Certainly, in other embodiments, other connection repairing methods can also be applied, without specific restrictions. At the same time, a number of the repairing sub-lines 211 is not limited to 2, and can also be 3 or more.

In this embodiment, the array substrate 200 comprises a plurality of sub-pixel electrodes (not shown in the figures) arranged in an array, each of the repairing lines 210 corresponds to a column of the sub-pixel electrodes 240, and each of the repairing sub-lines 211 is located in a gap of two adjacent sub-pixel electrodes. Each of the data lines Data also corresponds to a column of the sub-pixel electrodes, and is used to transmit data to the whole column of pixel units.

In this embodiment, one sub-pixel electrode is disposed between any two adjacent repairing sub-lines 211 on a same repairing line 210. As regions where the data lines Data intersect the repairing sub-lines 211 of the repairing lines 210 exist, when a line is conducted, a coupling capacity generated in the intersecting regions has bad effect on transmission of data in the data lines Data. Therefore, it is necessary to reduce an area of the intersecting regions of the data lines Data and the repairing sub-lines 211. Therefore, in other embodiments, two or more than two sub-pixel electrodes can be disposed between any two adjacent repairing sub-lines 211 on the same repairing line 210.

As shown in FIG. 3, a pixel driver circuit further includes a plurality of positive power supply voltage signal lines VDD and a plurality of operational voltage signal lines VI. The positive power supply voltage signal lines VDD and the operational voltage signal lines VI are disposed in the first metal layer.

The base substrate 200 further includes a second metal layer GE2, the second metal layer GE2 is disposed between the first metal layer GE1 and the base substrate, and a plurality of scanning lines and light-emitting control signal lines EM are disposed at intervals in the second metal layer GE2. Wherein, each stage of the pixel compensation circuit includes a scanning line of the (n−1)th stage Scan(n−1), a scanning line of the nth stage Scan(n), and a scanning line of the (x)th stage Scan(x), and the plurality of scanning lines intersect with the plurality of data lines.

As shown in FIG. 3, the array substrate further includes a polysilicon layer Poly. The base substrate, the polysilicon layer Poly, the second metal layer GE2, the first metal layer GE1, and the source drain electrode layer SD are sequentially arranged from bottom to top. An etched pattern of polysilicon is formed in the polysilicon layer Poly. The polysilicon layer intersects with the scanning lines, the light-emitting control signal lines and the data lines. A plurality of second connecting holes are provided in a region where the first metal layer GE1 intersects with the polysilicon layer Poly, and the data lines Data are connected to the polysilicon layer Poly through the second connecting holes. The positive power supply voltage signal lines VDD and the operational voltage signal lines VI can be connected with the pattern of polysilicon through other connecting holes.

A plurality of repairing lines 210 are disposed at intervals in the first metal layer GE1, at least two repairing sub-lines 211 are disposed at intervals on each of the repairing lines 210, and each of the repairing sub-lines 211 extends from each of the repairing lines 210 to a position of a projection of one of the data lines Data on the first metal layer GE1 along a direction of a thickness of the array substrate, and is insulated from the data lines Data in embodiments of this disclosure. When a disconnection point appears in the data lines Data, the repairing sub-lines 211 are connected with opposite ends of the disconnection point 220 to easily complete the repairing of the disconnection points of the data lines Data. At the same time, the repairing lines 210 are disposed in the first metal layer GE1, and the operational voltage signal lines formed on edges of the first metal layer are replaced with the data lines of the source-drain electrode layer SD and the pattern of polysilicon in the polysilicon layer, reducing a space of the array substrate occupied by the repairing lines 210 and simplifying a film structure of the array substrate 200.

The embodiments of this disclosure also provide a display device which includes the array substrate of the above embodiments. The display device can fulfill the same technical effects as the array substrate of the above embodiments. The descriptions are omitted herein.

### Third Embodiment

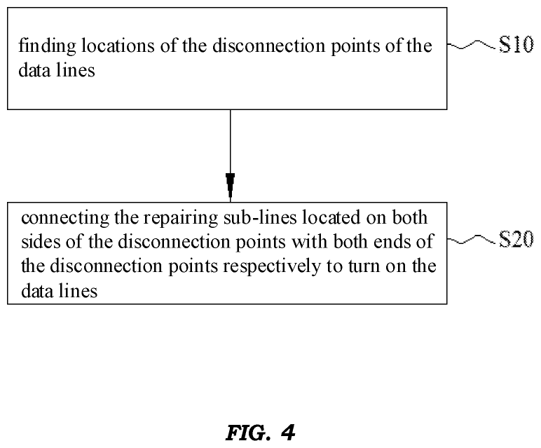

A repairing method of disconnection points of an array substrate is provided by embodiments of this disclosure, which is used in the array substrates provided by embodiments of this disclosure. A detailed description will be described in combination with FIG. 1 and FIG. 4. FIG. 4 shows a flow chart of a repairing method of disconnection points of data lines of an array substrate provided by embodiments of this disclosure, wherein the method includes steps of:

Step S10, finding locations of disconnection points of data lines; and

Step S20, connecting repairing sub-lines located on opposite sides of the disconnection points with opposite ends of the disconnection points respectively to conduct the data lines.

In this embodiment, when a disconnection point 120 appears in the data lines Data of the array substrate 100, the specific location of the disconnection point 120 in the data lines is located. A plurality of repairing sub-lines 111 are disposed at intervals on each of the repairing lines 110. The repairing sub-lines 111 located on opposite sides of the disconnection point 120 are connected to opposite ends of the disconnection point 120, which makes the repairing lines 110 and the repairing sub-lines 111 part of the data lines Data, so that the repairing of the disconnection point 120 of the data lines can be completed effectively, thus ensuring a conduction of the data lines Data.

In this embodiment, a method of connecting the repairing sub-lines 211 with opposite ends of the disconnection point 120 includes laser welding connection. Certainly, in other embodiments, other connection repairing methods can also be applied, without specific restrictions.

In the repairing method of disconnection points of an array substrate provided by embodiments of this disclosure, the repairing sub-lines on the data lines are connected to opposite ends of the disconnection point of the data lines, which makes the repairing lines and the repairing sub-lines part of the data lines, so that the repairing of the disconnection point of the data lines can be completed effectively, thus ensuring a conduction of the data lines. Furthermore, the repairing processes are simple and success rate of repair is high.

In conclusion, although the disclosure is disclosed as above in the preferred embodiment, the above preferred embodiment is not used to limit the disclosure. To a person having ordinary skill in the art, various changes and embellishments can be made within the spirit and scope of the disclosure. Therefore, the scope of protection of the disclosure is based on the scope defined in the claims.

What is claimed is:

1. An array substrate, comprising a base substrate, and a first metal layer and a source-drain electrode layer sequentially stacked on the base substrate;
wherein a plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines.

2. The array substrate of claim 1, wherein when a disconnection point appears in the data lines, the repairing sub-lines located on opposite sides of the disconnection point are connected with opposite ends of the disconnection point.

3. The array substrate of claim 1, wherein the array substrate comprises a plurality of sub-pixel electrodes arranged in an array, each of the repairing lines corresponds to a column of the sub-pixel electrodes, and each of the repairing sub-lines is located in a gap of two adjacent sub-pixel electrodes.

4. The array substrate of claim 2, wherein at least one of the sub-pixel electrodes are disposed between any two adjacent repairing sub-lines on a same repairing line.

5. The array substrate of claim 1, wherein extending directions of the repairing sub-lines on a same repairing line are same.

6. The array substrate of claim 1, wherein the array substrate further comprises an insulating interlayer, the insulating interlayer is disposed between the first metal layer and the source-drain electrode layer, and when a disconnection point appears in the data lines, the repairing sub-lines are connected to opposite ends of the disconnection point through a first connecting hole penetrating the insulating interlayer.

7. The array substrate of claim 1, wherein the array substrate further comprises a second metal layer, a plurality of scanning lines are disposed at intervals in the second metal layer, and the scanning lines intersect with the data lines.

8. The array substrate of claim 7, wherein the array substrate further comprises a polysilicon layer, the polysilicon layer is located between the second metal layer and the base substrate, a second connecting hole is provided in a region where the first metal layer intersects the polysilicon layer, and the data lines are connected to the polysilicon layer through the second connecting hole.

9. A repairing method of disconnection points of an array substrate, wherein the array substrate comprises a base substrate, and a first metal layer and a source-drain electrode layer sequentially stacked on the base substrate;
wherein a plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines, and the method comprises steps of:
finding locations of the disconnection points of the data lines; and
connecting the repairing sub-lines located on opposite sides of the disconnection points with opposite ends of the disconnection points respectively to conduct the data lines.

10. A display device comprising an array substrate, wherein the array substrate comprises a base substrate, and a first metal layer and a source-drain electrode layer sequentially stacked on the base substrate;
wherein a plurality of data lines are disposed at intervals in the source-drain electrode layer, a plurality of repairing lines are disposed at intervals in the first metal layer, at least two repairing sub-lines are disposed at intervals on each of the repairing lines, and each of the repairing sub-lines extends from one of the repairing lines to a position of a projection of each of the data lines on the first metal layer along a thickness direction of the array substrate, and is insulated from the data lines.

11. The display device of claim 10, wherein when a disconnection point appears in the data lines, the repairing sub-lines located on opposite sides of the disconnection point are connected with opposite ends of the disconnection point.

12. The display device of claim 10, wherein the array substrate comprises a plurality of sub-pixel electrodes arranged in an array, each of the repairing lines corresponds to a column of the sub-pixel electrodes, and each of the repairing sub-lines is located in a gap of two adjacent sub-pixel electrodes.

13. The display device of claim 11, wherein at least one of the sub-pixel electrodes are disposed between any two adjacent repairing sub-lines on a same repairing line.

14. The display device of claim 10, wherein extending directions of the repairing sub-lines on a same repairing line are same.

15. The display device of claim 10, wherein the array substrate further comprises an insulating interlayer, the insulating interlayer is disposed between the first metal layer and the source-drain electrode layer, and when a disconnection point appears in the data lines, the repairing sub-lines are connected to opposite ends of the disconnection point through a first connecting hole penetrating the insulating interlayer.

16. The display device of claim 10, wherein the array substrate further comprises a second metal layer, a plurality of scanning lines are disposed at intervals in the second metal layer, and the scanning lines intersect with the data lines.

17. The display device of claim 16, wherein the array substrate further comprises a polysilicon layer, the polysilicon layer is located between the second metal layer and the base substrate, a second connecting hole is provided in a region where the first metal layer intersects the polysilicon layer, and the data lines are connected to the polysilicon layer through the second connecting hole.
